(19) United States
(12) Patent Application Publication
(10) Pub. No.: US 2001/0004557 A1
(43) Pub. Date: Jun. 21, 2001

(54) Flat conductor ribbon cable

(76) Inventors: Wolfgang Scheideler, Leuchtenberg (DE); Heinz-Jurgen Hemken, Herzogenrath (DE); Helmut Steinberg, Stornstein (DE); Peter Zamzow, Bochum (DE)

Correspondence Address: SUGHRUE, MION, ZINN, MACPEAK & SEAS, PLLC, 2100 Pennsylvania Avenue, N.W., Washington, DC, 20037-3213, US

(21) Appl. No.: 09/734,722

(22) Filed: Dec. 13, 2000

(30) Foreign Application Priority Data
Dec. 15, 1999 (DE) 19960465.7

(51) Int. Cl. H01B 11/00; H05K 1/00

(52) U.S. Cl. 439/67; 174/117 FF

(57) ABSTRACT

A flat conductor ribbon cable (1) in which at least two flat electric conductors (2) with rectangular cross-section are embedded, separated and in parallel, in insulating material (3). For effective electric shielding, a metallic envelope (4), which is produced by application of a process for surface coating and is completely closed, is applied to the entire outer surface of the flat cable (1) including the lateral edges (6,7) and adheres firmly to the insulating material (3) of the flat cable (1).

### BACKGROUND OF THE INVENTION

This application is based on and claims the benefit of German Patent Application No. 19960465.7 filed Dec. 15, 1999, which is incorporated by reference herein.

The invention concerns a flat conductor ribbon cable in which at least two flat electric conductors with rectangular cross-section are embedded, separated and in parallel, in insulating material, e.g., as described in published German patent application DE-AS 26 43 838.

These types of electrical cables—referred to in the following as “FCRC”—are advantageously used in, for example, the circuitry for various electrical devices and in automobile construction. As planar shapes, they have small dimensions, so that they occupy little space. Good mechanical protection results because the flat conductors are firmly embedded in the insulating material of the FCRC. In particular, there is no danger of buckling, even if the FCRC is bent around small radii. The FCRC is therefore also distinguished by good flexibility. This is also true for the FCRC according to the earlier mentioned DE-AS 26 43 838, in which the conductors are embedded between two films of insulating material, which are firmly attached to the conductors and to one another, in the so-called lamination process.

In many cases, it is necessary to equip the FCRC with an electrically effective shield. Such a shield should make ineffective those interfering signals which arise from the FCRC itself, as well as those which could be coupled into the FCRC from outside (electromagnetic compatibility or EMC). Metal foils of aluminum or copper could, for example, be laminated onto both of the flat sides of the FCRC as a shield. Such a shield can be sealed onto the very narrow lateral edges of the FCRC in an electrically effective way only through costly additional measures. Another possibility for production of a shield is the application of a braid of metallic wires, which could consist of copper or aluminum. This measure is very costly and time-consuming.

### SUMMARY OF THE INVENTION

It is an object of the invention to provide the above-described FCRC with an electrically effective shield in a simple manner.

This object is solved according to the invention in that a completely closed metallic envelope, which adheres firmly to the insulating material, is applied to the entire external surface of the FCRC, including the lateral edges, through the use of a surface coating process.

The FCRC is completely embedded in a closed metallic envelope by the use of a process, known in and of itself, for physical or chemical surface coating and is thereby provided with an electrically effective shield which is continuous over its entire length. It is thereby “sealed” in both directions against interfering signals. This fact is surprising for the geometrically problematical shaped “FCRC”, as not only its large surface flat sides, but also its very thin lateral edges, are coated without interruptions and without any additional measures being necessary. The metallic envelope is therefore completely closed. Because the physically or chemically applied material of the metallic envelope, which is preferably copper, binds firmly with the insulating material of the FCRC, the envelope is automatically mechanically protected, even if only a modest film thickness is used for the envelope. This is particularly true during bending of the FCRC. The metallic envelope remains firmly affixed to the FCRC even at small bending radii. The FCRC is not only electrically shielded, but also simultaneously protected against chemical stresses and oil by the closed metallic envelope.

Physical processes, e.g., PVD (physical vapor deposition), or chemical processes, e.g., CVD (chemical vapor deposition), could be used for the coating. In a preferred embodiment, a PVD process is used for the production of the metallic envelope, although this is merely representative of all other suitable coating processes. A completely closed metallic envelope which adheres firmly to the FCRC, even without a bonding agent, results in particular when the PVD process is used.

### BRIEF DESCRIPTION OF THE DRAWINGS

An example of the invention will now be described with reference to the drawings, wherein:

FIG. 1 shows a top view of an FCRC according to the invention;

FIG. 2 shows a section through FIG. 1 along the line II-II in an enlarged view; and

FIG. 3 shows a schematic view of an arrangement for coating of the FCRC.

### DETAILED DESCRIPTION OF THE INVENTION

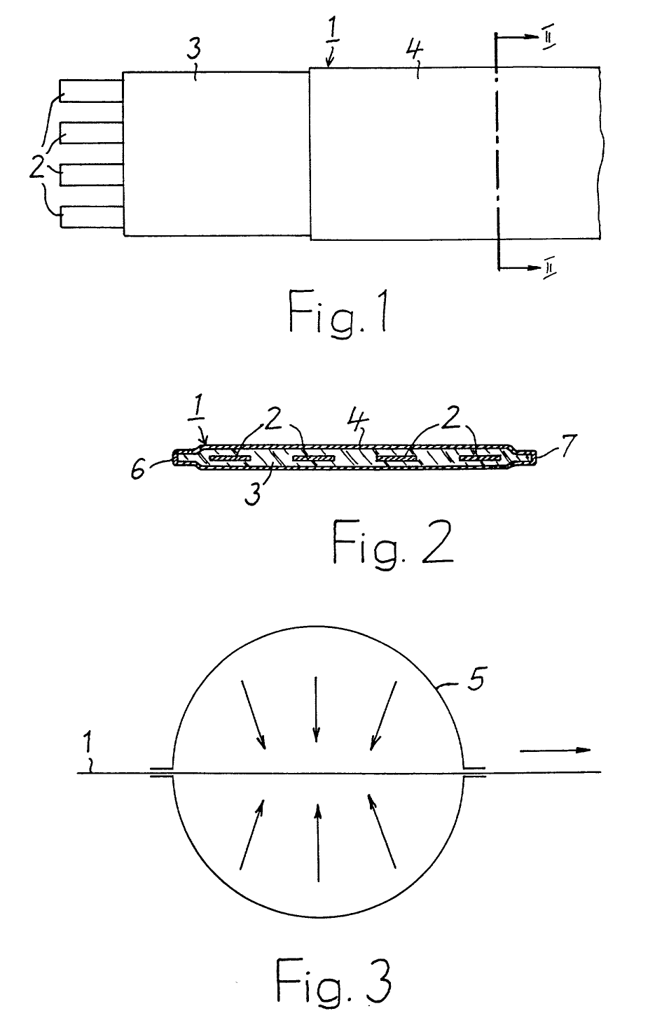

An FCRC 1 is depicted in FIG. 1 which, in this exemplary embodiment, has four flat conductors 2 with rectangular cross-section. The conductors 2 consist of copper. In a typical FCRC, they are from approximately 40 μm to 200 μm thick. There should be at least two conductors 2, although their quantity can be selected as desired within a normal range. The conductors 2 are embedded in an insulation 3 which can consist of any desired insulating material. The conductors 2 are arranged fixedly and immovably in the insulation 3, and are separated and in parallel. The insulation 3 can, for example, consist of two films coated with an adhesive which are applied in a so-called lamination process to two different sides of the conductors 2 and are firmly attached to one another. The thickness of the foils in the typical embodiment, including the adhesive layer, is approximately 75 μm to 90 μm. The insulation 3 can, however, also be produced through extrusion. Polyethylene is used as the insulation material in a preferred embodiment.

A completely closed metallic envelope 4, which is produced through the use of the PVD process, is applied over the insulation 3 of the FCRC 1. A layer applied with this process to a substrate consisting of insulating material adheres firmly to the insulating material. The envelope 4 has a thickness between 500 nm and 2 μm in a preferred embodiment. The PVD process is described in the following as an example of the production of an envelope 4:

If the envelope 4 is to consist of copper, a quantity of copper sufficient for the coating of a known length of an FCRC 1 is placed in a vacuum chamber 5 in which it is cathodically atomized after sufficient heating and application of an electrical potential. Continuous discharges are hereby produced in a so-called cathode gun so that the copper goes into a vapor phase. An FCRC 1 drawn through the vacuum chamber 5 can thus be completely coated with copper in a continuous operation.

The FCRC 1 in this process passes through locks, not shown for the sake of simplicity, which ensure that the vacuum in the vacuum chamber 5 can be maintained. It is essential that not only the flat sides of the FCRC 1 are coated in the vacuum chamber 5, but also the narrow lateral edges 6 and 7. The lateral edges 6 and 7 could almost be called sharp-edged. They have, corresponding to the numerical values given above, a wall thickness of approximately 150 μm to 180 μm. In spite of these very small dimensions, the lateral edges 6 and 7 are also completely coated. The envelope 4 is therefore completely closed without further measures after leaving the vacuum chamber 5.

What is claimed is:

1. A ribbon cable in which at least two electric conductors are embedded, separated and in parallel, in insulating material, said cable further comprising a surface coating applied to the entire external surface of the ribbon cable, including lateral edges of said ribbon cable, and firmly adhering to the insulating material of the ribbon cable to form a completely closed metallic envelope.

2. A cable according to claim 1, wherein each of said electrical conductors has a substantially rectangular cross-section.

3. A process for the production of a shielded ribbon cable, comprising the steps of providing a ribbon cable in which at least two electric conductors are embedded, separated and in parallel, in insulating material, and applying a surface coating to the entire external surface of the ribbon cable, including lateral edges of said ribbon cable, to form a completely closed metallic envelope.

4. A process according to claim 3, wherein each of said electrical conductors has a substantially rectangular cross-section.

5. A process according to claim 3, wherein said surface coating is applied by a physical vapor deposition process.

6. A process according to claim 3, wherein said surface coating is applied by a chemical vapor deposition process.
